(19) United States
(12) Patent Application Publication
(10) Pub. No.: US 2011/0159212 A1
(43) Pub. Date: Jun. 30, 2011

(54) INSULATING FILM MATERIAL, METHOD FOR FORMING FILM BY USING THE INSULATING FILM MATERIAL, AND INSULATING FILM

(75) Inventors: Takahisa Ohno, Tsukuba-shi (JP); Nonuo Tajima, Ibaraki (JP); Yoshiaki Inaishi, Tsuchiura-shi (JP); Manabu Shinriki, Tokyo (JP); Kazuhiro Miyazawa, Tokyo (JP)

(73) Assignees: National Institute for Materials Science, Tsukuba-shi, Ibraki (JP); TAIYO NIPPON SANSO CORPORATION, Tokyo (JP)

(21) Appl. No.: 13/060,525

(22) PCT Filed: Sep. 1, 2009
(86) PCT No.: PCT/JP2009/004298

§ 371 Date: Feb. 24, 2011

(30) Foreign Application Priority Data
Sep. 1, 2008 (JP) 2008-223907

(51) Int. Cl. C23C 16/44; C07F 7/08; H05H 1/24

(52) U.S. Cl. 427/569; 556/406

(57) ABSTRACT

An insulating film material for plasma CVD, wherein the material is represented by the chemical formula (1); a film forming method using the material; and an insulating film;

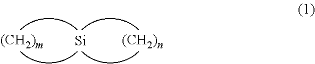

(in the formula, m and n represent integer of 3 to 6, and m and n may be the same or different from each other in a molecule.)

### TECHNICAL FIELD

The present invention relates to an insulating film material, which is used when an insulating film is formed, a film forming method using the material, and an insulating film.

Priority is claimed on Japanese Patent Application No. 2008-223907, filed Sep. 1, 2008, the content of which is incorporated herein by reference.

### BACKGROUND ART

The miniaturization of a wiring layer has been progressing, accompanied by high integration of semiconductor devices. However, when a finely fabricated wiring layer is used, the influence of a signal delay caused by the wiring layer is large, and an increase in signal transmission speed is prevented. The signal delay is relative to the resistance of a wiring layer and the capacitance between wiring layers. A low resistance in the wiring layer and a decrease in capacitance between wiring layers are essential to achieve a high speed signal transmission.

Therefore, as a material which forms a wiring layer, copper having a low resistivity has recently been used instead of conventionally used aluminum. Furthermore, an interlayer dielectric film having a low dielectric constant is used to further decrease capacitance between wiring layers.

For example, as an interlayer dielectric film, a SiO₂ film has a dielectric constant of 4.1 and a SiOF film has a dielectric constant of 3.7. However, in recent years, a SiOCH film and an organic film, which have an even smaller dielectric constant, are used.

The dielectric constant of an interlayer dielectric film has gradually decreased in recent years as described above. Research and development have been performed in order to form an interlayer dielectric film having a low dielectric constant of 2.4 or less to be used in the next generation device, and an interlayer dielectric film having a dielectric constant of less than 2.00 has been reported recently.

With respect to interlayer dielectric films which have been proposed, copper tends to be diffused in the films. Accordingly, when a multi-layered wiring structure is adopted in which copper is used for the wiring layer, an insulating film having copper diffusion barrier properties is generally provided at the boundary between a copper wiring layer and an interlayer dielectric film in order to prevent copper diffusion into the dielectric film.

As the insulating film having copper diffusion barrier properties, an insulating film consisting of SiCN, silicon nitride or the like, which has superior copper diffusion barrier properties, has been used. However, the dielectric constant of the films is 4 to 7 and is therefore high. Such a high dielectric constant thereof increases a practical dielectric constant of insulating films as a whole which form a multilayered wiring structure.

For example, if an interlayer dielectric film having a dielectric constant of about 2.5 is used, a practical dielectric constant of a multilayered wiring structure is about 3 when the multilayered wiring structure includes the interlayer dielectric film wherein a dielectric constant thereof is about 2.5 and an insulating film having copper diffusion barrier properties wherein the dielectric constant thereof is about 4.0.

Accordingly, it is required to decrease the dielectric constant of an insulating film having copper diffusion barrier properties in order to decrease the practical dielectric constant of the multilayered wiring structure, and research and development have been performed in order to achieve a low dielectric constant.

For example, an insulating film having copper diffusion barrier properties was reported, wherein silicon and carbon were included as main components and an organosilane based material having a π electron coupling was used. (Refer to patent document 1)

However, even in the insulating film having copper diffusion barrier properties disclosed in Patent document 1, there are problems such that the dielectric constant thereof is 3.9 and is therefore high, and copper diffusion barrier properties thereof is not particularly good as compared with that of a conventional insulating film which consists of SiCn.

As described above, an insulating film has been desired, which can achieve a good balance between a low dielectric constant and copper diffusion barrier properties, and, more preferably, is made of materials that do not include oxygen which causes oxidation of copper. However, such an insulating film has not yet been reported.

### PRIOR ART DOCUMENT

Patent Document 1: Japanese Unexamined Patent Application, First Publication No. 2005-45058

### SUMMARY OF THE INVENTION

### Problem to be Solved by the Invention

The purpose of the present invention is to obtain an insulating film which has copper diffusion barrier properties but has an extremely low dielectric constant.

### Means for Solving the Problems

In order to achieve the purpose, the following invention is provided.

(i) The first aspect of the present invention is an insulating film material for plasma CVD represented by the following chemical formula (1).

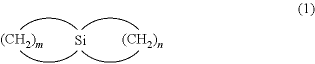

(In the formula, m and n represent integer of 3 to 6, and m and n may be the same or different from each other in a molecule.)

(ii) The insulating film material for plasma CVD of the present invention is characterized in that a molecule of the material includes no oxygen.

(iii) The insulating film material for plasma CVD of the present invention is characterized in that a molecule of the material includes no carbon-carbon double bond.

(iv) The insulating film material for plasma CVD of the present invention is characterized in that a molecule of the material includes two ring structures which consist of CH₂ and bond to silicon.

(v) The second aspect of the present invention is a film forming method wherein an insulating film is formed by plasma CVD using the insulating film material which is described in any of the aforementioned (i) to (iv).

(vi) It is preferable that carrier gas does not exist with a film, when the film is formed by the film forming method of the second aspect.

(vii) The third aspect of the present invention is an insulating film which is obtained by the film forming method of the (v) or (vi).

(viii) It is preferable that the insulating film of the third aspect of the present invention has a dielectric constant of 3.5 or less.

(iv) The fourth aspect of the present invention is the use of the insulating film material of the first aspect of the present invention to form an insulating film by plasma CVD method.

It is preferable that an insulating film of the present invention is an interlayer dielectric film of a multilayered wiring structure which includes a wiring layer and the interlayer dielectric film.

It is preferable that an insulating film of the present invention is an insulating film having copper diffusion barrier properties of a multilayered wiring structure, wherein the structure includes a wiring layer, the insulating film having copper diffusion barrier properties and an interlayer dielectric film.

The dielectric constant of an insulating film of the present invention is preferably 2.9 to 3.5.

### Effect of the Invention

Due to the present invention, an insulating film formed by a plasma CVD method using an insulating film material, which is a silicon material represented by the aforementioned chemical formula (1), has a low dielectric constant and superior copper diffusion barrier properties.

### BRIEF DESCRIPTION OF THE DRAWINGS

FIG. 1 is a schematic configuration view which shows one example of a film forming device which can be used in the film forming method of the present invention.

FIG. 2 is a graph which shows the evaluation method of copper diffusion barrier properties used in the present invention.

FIG. 3 is a graph which shows the evaluation method of copper diffusion barrier properties used in the present invention.

FIG. 4 is a graph which shows the evaluation result of copper diffusion barrier properties obtained in Example 1.

FIG. 5 is a graph which shows the evaluation result of copper diffusion barrier properties obtained in Example 2.

FIG. 6 is a graph which shows the evaluation result of copper diffusion barrier properties in Example 3.

FIG. 7 is a graph which shows the evaluation result of copper diffusion barrier properties obtained in Comparative Example 1.

FIG. 8 is a graph which shows the evaluation result of copper diffusion barrier properties obtained in Comparative Example 2.

FIG. 9 is a graph which shows the evaluation result of copper diffusion barrier properties obtained in Comparative Example 3.

### BEST MODE FOR CARRYING OUT THE INVENTION

The present invention relates to an insulating film material which can be used to form an insulating film, which is suitable as an interlayer dielectric film of a semiconductor device or the like, a film forming method using the material, and an insulating film. According to the present invention, it is possible to obtain an insulating film which has copper diffusion barrier properties and a low dielectric constant.

Hereinafter, the present invention is explained in detail.

An insulating film material used for the plasma CVD of the present invention is a silicon compound represented by the chemical formula (1). The material may be any of conventional compounds which are included in the range of the formula, and may be formed by any of conventional method. It has not been known until now that the compound represented by the chemical formula (1) is used as a material for forming an insulating film having copper diffusion barrier properties. The present invention has been discovered by the inventors as the result of diligent study performed to overcome the aforementioned problems.

The silicon compound has two ring structures in the molecule thereof, wherein the ring structures are selected from three-membered ring to six-membered ring, and in any ring structure, carbon atoms which exist at both ends of (CH)ₘ and (CH)ₙ directly bonds to silicon. Furthermore, no double bond is included in the ring structures.

As a concrete example of a compound represented by the general formula (1), 5-silaspiro[4.4]nonane (m=4 and n=4 in the chemical formula (1)) is cited as a preferable compound.

Usable examples of the silicon compound other than 5-silaspiro[4.4]nonane include 4-silaspiro[3.3]heptane, 4-silaspiro[3.4]octane, 4-silaspiro[3.5]nonane, 4-silaspiro[3.6]decane, 5-silaspiro[4.5]decane, 5-silaspiro[4.6]undecane, 6-silaspiro[5.5]undecane, 6-silaspiro[5.6]dodecane and 7-silaspiro[6.6]tridecane.

Next, the film forming method of the present invention is described below.

A film forming method of the present invention is generally performed by plasma CVD method using an insulating film material represented by the aforementioned chemical formula (1). In this method, one silicon compound, or a mixture of two or more silicon compounds represented by the chemical formula (1) may be used.

When a mixture of two or more insulating film materials is used, the mixing ratio thereof is not particularly limited. The mixing ratio can be determined by taking the dielectric constant, copper diffusion barrier properties or the like of a target insulating film into consideration.

Furthermore, when a film is formed, a carrier gas may be added to the aforementioned insulating film material which is a silicon compound represented by the chemical formula (1). However, it is preferable to form a film using merely the insulating material of the present invention in order to improve copper diffusion barrier properties.

Examples of the aforementioned carrier gas include gas which does not include oxygen such as inert gas such as helium, argon, krypton or xenon, and hydrocarbons such as nitrogen, hydrogen, methane or ethane. However, the carrier gas is not limited thereto. The carrier gas may be used in combination of two or more gases. The mixing ratio of carrier gases is not particularly limited, as well as the mixing ratio of an insulating material, which is not particularly limited.

Accordingly, a gas used for forming a film, wherein the gas is transferred into a chamber of a film forming device to form a film, may be a gas consisting of an insulating film material or a mixing gas which includes a carrier gas.

When an insulating film material and a carrier gas are materials which are in a gaseous state at room temperature, they can be used as they are. When an insulating film material and a carrier gas are materials which are in a liquid state at room temperature, gasification of the materials can be performed. The gasification may be any of gasification wherein bubbling is performed using an inert gas such as helium, gasification wherein a vaporizer is used, or gasification wherein heating is performed.

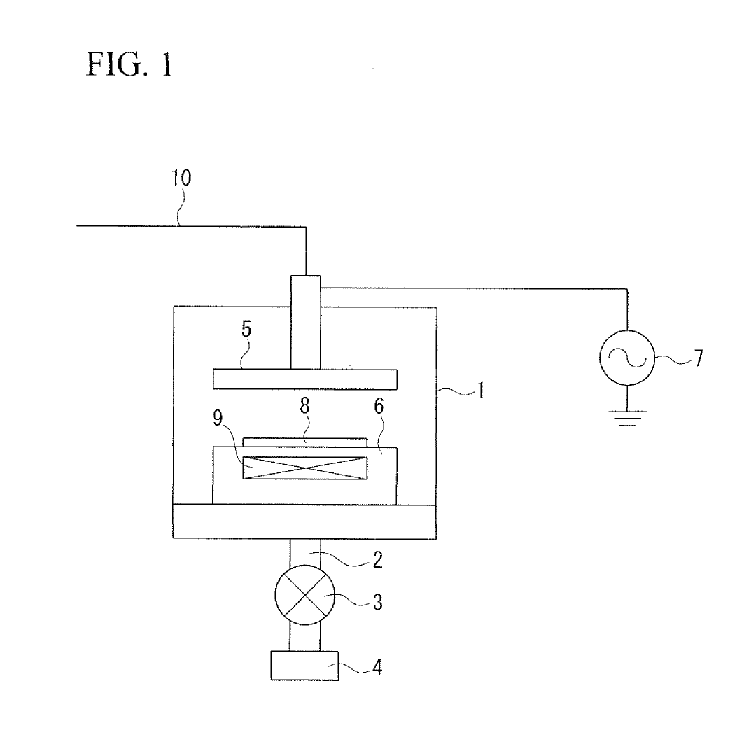

As the plasma CVD method, well-known methods can be used, and any method can be selected as necessary. For example, a film can be formed using a parallel plate plasma type film forming device which is shown in FIG. 1.

The plasma film forming device shown in FIG. 1 is equipped with a chamber 1 wherein internal pressure can be reduced, and the chamber 1 connects to an exhaust pump 4 via an exhaust pipe 2 and an on-off valve 3. The chamber 1 also has a pressure gauge, which is not illustrated, to measure pressure within the chamber 1. In the chamber 1, a pair of plate-like upper electrodes 5 that face each other and a lower electrode 6 are provided. The upper electrodes 5 are connected to a high frequency power source 7 to apply a high frequency current to the upper electrodes 5.

The lower electrode 6 can be used as a mount stand to mount a substrate 8, and a heater 9 is provided in the lower electrode 6 so that a substrate can be heated.

Furthermore, a gas supply pipeline 10 is connected to the upper electrodes 5. It is structured such that the gas supply pipeline 10 is connected with a non-illustrated supply source of a gas which is used for forming a film, to supply the gas from the supply device, and then, the supplied gas passes through plural through holes formed in the upper electrode 5 and flows out toward the lower electrode 6 while diffusing.

The aforementioned gas supply source for forming a film is equipped with a vaporizer which vaporizes the aforementioned insulating film material of the present invention, a flow control valve which controls the flow rate of the generated gas, and a supply device which supplies a carrier gas. It is structured such that a carrier gas is also passed through a supply pipeline 10 and is supplied from the upper electrode 5 into a chamber 1.

When a film is formed, a substrate 8 is provided on a lower substrate 6 which exists in a chamber 1 of a plasma film forming device, and then a supply source, which supplies a gas for forming a film, supplies said gas in the chamber 1 to form a film. High-frequency electric current is applied to an upper electrode 5 from a high frequency power source 7 to generate plasma in the chamber 1. As the result, an insulating film is generated which is obtained from a vapor phase chemical reaction using the aforementioned gas which is prepared for forming a film.

As the substrate 8, a substrate which is a silicon wafer is mainly used. Another insulating film, a conductive film, and/or a wiring structure may have been formed in advance on the silicon wafer.

As the plasma CVD method used in the present invention, it is possible to use ICP plasma, ECR plasma, magnetron plasma, high frequency plasma, microwave plasma, capacity coupled plasma and inductively coupled plasma as well as the parallel plate type method. Dual frequency excitation plasma, wherein a high frequency is also applied to a lower electrode 6 of the parallel plate type device, is also usable.

The following ranges are preferable as conditions for forming a film using the plasma film forming device, but not limited thereto.

Flow of an insulating film material: 15 to 100 cc/minute (it is a total value when two or more materials are used.)

Flow of a carrier gas: 0 to 80 cc/minute

Pressure: 1 to 1330 Pa

RF power: 50 to 500 W, and preferably 50 to 250 W

Substrate temperature: 400° C. or less

Reaction time: 1 to 180 seconds

Thickness of a formed film: 100 to 200 nm

Next, an insulating film of the present invention is explained.

An insulating film of the present invention can be formed according to the plasma CVD method with the aforementioned insulating film material used for plasma CVD, or with the material and a carrier gas, by a plasma film forming device. The dielectric constant of the film is 3.5 or less in general, and more preferably 2.9 to 3.5. The latter range enables even better copper diffusion barrier properties. The insulating film does not include oxygen, but is structured from silicon, hydrogen and carbon.

The reason why an insulating film formed by the insulating film forming method of the present invention shows excellent copper diffusion barrier properties and has a low dielectric constant is assumed to be as follows.

In a silicon compound which is an insulating film material of the present invention, bond energy of a C—C part in a cyclic structure which bonds to silicon is the lowest, and therefore, said bond is cleaved by plasma to open the cyclic structure.

A ring-opened cyclic structure having CH₂ is accumulated on a substrate, while the structure bonds with another ring-opened cyclic structure having CH₂. In other wards, a CH₂ network structure such as Si—CH₂—CH₂—Si and Si—CH₂—Si is formed, and due to the network structure, an insulating film which has a dense structure but has a low dielectric constant can be formed.

Furthermore, an insulating material of the present invention does not include oxygen. Accordingly, when an insulating film is formed in a plasma atmosphere, copper which forms a conductive film is not oxidized. Therefore, an insulating film can be formed wherein copper ions which have a large influence on copper diffusion properties are hardly generated.

Accordingly, an insulating film of the present invention is an insulating film which has copper diffusion properties and a low dielectric constant.

Hereinafter, examples of the present invention are explained in detail based on Examples and Comparative Examples. However, the present invention is not limited to the following Examples.

### Example 1

### Formation of an Insulating Film Wherein a Carrier Gas was not Used

An insulating film was generated as follows.

An insulating film was formed using a parallel plate type capacity coupled plasma CVD device, such that an 8 inch silicon wafer (a diameter: 200 mm) was transferred on a susceptor, which had been heated at 350° C. in advance, and 5-silaspiro[4.4]nonane was allowed to flow in the device at the volume flow rate of 20 cc/min as an insulating film material gas, while output of a high frequency power supply device for generating plasma was 180 W. When the film was formed, the internal pressure of a chamber of the plasma CVD device was 133 Pa.

(Measurement of Dielectric Constant)

The aforementioned silicon wafer was transferred on a CV measurement device 495 manufactured by SSM, Inc., in order to measure the dielectric constant of the obtained insulating film, and the dielectric constant of the insulating film was measured using a mercury electrode. Measurement results are shown in Table 1.

(Evaluation of Copper Diffusion Barrier Properties)

Copper diffusion barrier properties of obtained films were evaluated using a method wherein figures of the current-voltage (I-V) characteristics of the obtained insulating films were prepared in each case wherein a copper electrode (hereinafter, referred as a Cu electrode) or aluminum electrode (hereinafter, referred as an Al electrode) was used for the film, and the difference of the characteristics was compared.

This method is a biased temperature stress test method which uses acceleration of copper diffusion into an insulating film, wherein the acceleration is caused by applying electric field while the insulating film is heated at about 100 to 300° C.

The method is further explained below. For example, when an insulating film which does not have copper diffusion barrier properties is prepared as an evaluation film, the I-V characteristic of the film, wherein a Cu electrode is used for the film, is different from the I-V characteristic of the film, wherein an Al electrode is used for the film. The difference is caused for the reasons described below. When a Cu electrode is used for the film and electric field is applied, thermal diffusion of copper ions into an insulating film is accelerated at the Cu electrode, copper ion drift is caused which increases a leak current. On the other hand, when an Al electrode is used for the film, the leak current does not increase since thermal diffusion of copper ions is not caused. Accordingly, due to the comparison of the I-V characteristic when a Cu electrode is used and the I-V characteristic when an Al electrode is used, copper diffusion barrier properties of an insulating film can be evaluated. When the difference between the former I-V characteristic and the latter I-V characteristic is small, it can be determined that the insulating film has superior copper diffusion barrier properties.

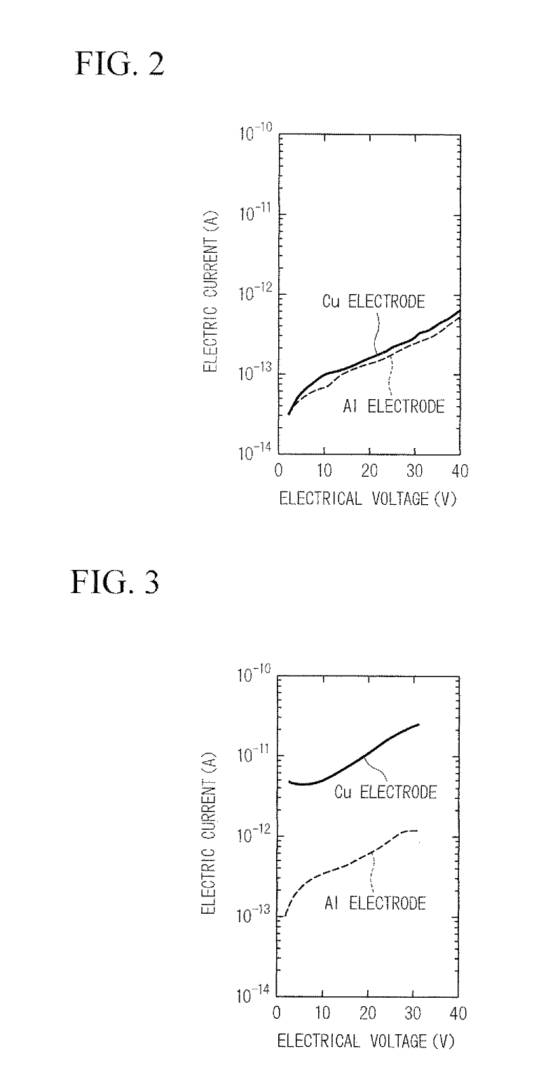

FIG. 2 is a graph which shows the characteristics of an insulating film which was formed with a material having high copper diffusion barrier properties, and the I-V characteristic when a Cu electrode was used for the film and the I-V characteristic when an Al electrode was used for the film are shown. That is, the I-V characteristic when a Cu electrode was used and the I-V characteristic when an Al electrode was used are almost the same in the example.

FIG. 3 is a graph which shows the characteristics of an insulating film which was formed with a material having low copper diffusion barrier properties. In this example, the difference between the I-V characteristic when a Cu electrode was used for the film and the I-V characteristic when an Al electrode was used for the film is large, such that the current value of the I-V characteristic when a Cu electrode was used is higher by two or more orders of magnitude than the current value of that when an AL electrode was used.

In this way, when the I-V characteristic when a Cu electrode is used is almost equal to that of when an Al electrode is used, it can be determined that copper diffusion barrier properties thereof are high. On the other hand, when the I-V characteristic when a Cu electrode is used is one or more orders in magnitude higher than that of when an Al electrode is used, it can be determined that copper diffusion barrier properties thereof are low.

The following document can be referred to for the test method.

Alvin L. S. Loke et al., IEEE TRANSACTIONS ON ELECTRON DEVICES, vol. 46, No. 11, 2178-2187 (1999)

Hereinafter, a concrete evaluation procedure of copper diffusion barrier properties, which was used for insulating films obtained in Examples, is shown.

First, two samples to be measured were cut so as to have an area of about 30 mm². After masks are provided thereon, a Cu electrode having a diameter of about 1 mm was formed on one of the samples, and an Al electrode having a diameter of about 1 mm was also formed on the other sample, using a vacuum deposition method.

Next, the sample prepared to be evaluated which had the Cu electrode thereon was provided in a vacuum probe device, and the I-V characteristic of the sample was measured by the CV measuring device under the vacuum atmosphere which was less than 0.133 Pa. Then, nitrogen was supplied in the vacuum probe device until the pressure therein became about 93 kPa and the stage temperature was increased to 140° C. or 200° C., and the IV characteristic was measured by the CV measuring device. The stage temperature used was shown in each figure. Regarding a film having high copper diffusion barrier properties, measurements were performed at the higher stage temperature (200° C.). When measurement is performed at the higher stage temperature, accelerated evaluation can be performed regarding Cu diffusion.

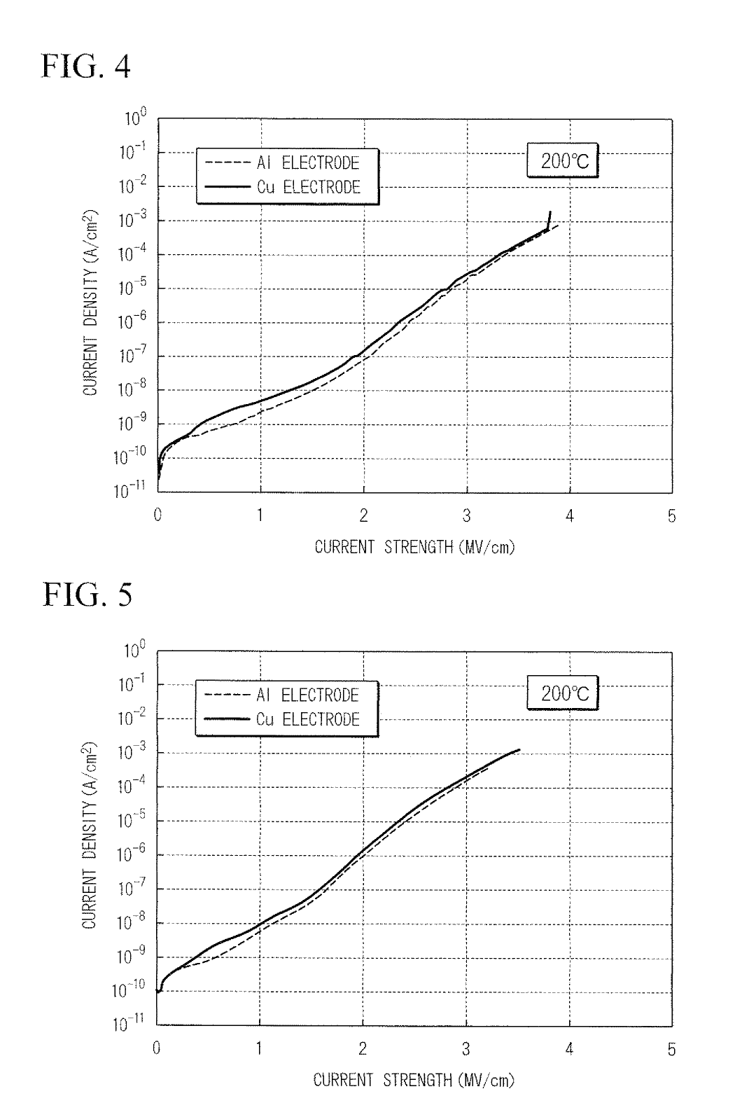

The sample on which the Al electrode had been provided was measured, similar to the aforementioned measurement of the I-V characteristic of the sample on which the Cu electrode had been provided. Subsequently, copper diffusion barrier properties of the formed insulating film were evaluated based on the differences between the I-V characteristic of the sample using the Cu electrode and I-V characteristic of the sample using the Al electrode. The evaluation results of the I-V characteristics of the insulating film which was obtained in Example 1 were shown in FIG. 4.

A spectrum ellipsometry device manufactured by Five Lab Corporation was used, when the thickness was measured to determine a dielectric constant based on the thickness.

The evaluation results of copper diffusion barrier properties are shown in Table 1.

### Example 2

### Formation of an Insulating Film Wherein a Carrier Gas was not Used

An insulating film was prepared such that the method and devices used in Example 2 were similar to those of Example 1 except that 5-silaspiro[4,4]nonane was allowed to flow at the volume flow rate of 35 cc/min as a material gas, and output of a high frequency power source device for generating plasma was 150 W to form an insulating film. When the film was formed, the internal pressure of a chamber of the plasma CVD device was 66.6 Pa.

The dielectric constant, copper diffusion barrier properties and the thickness of the obtained insulating film were evaluated similar to those of Example 1. The evaluation results were shown in Table 1. The evaluation results of copper diffusion barrier properties are shown in FIG. 5.

### Example 3

### Formation of an Insulating Film Wherein a Carrier Gas was Used

An insulating film was prepared such that the method and devices used in Example 3 were similar to those of Example 1 except that 5-silaspiro[4,4]nonane was allowed to flow at the volume flow rate of 17 cc/min as a material gas, helium was also allowed to flow as a carrier gas at the rate of 40 cc/min, and output of a high frequency power supply device for generating plasma was 150 W to form an insulating film. The internal pressure of a chamber of the plasma CVD device was 266 Pa.

The dielectric constant, copper diffusion barrier properties and the thickness of the obtained insulating film were evaluated similar to those of Example 1.

The evaluation results are shown in Table 1.

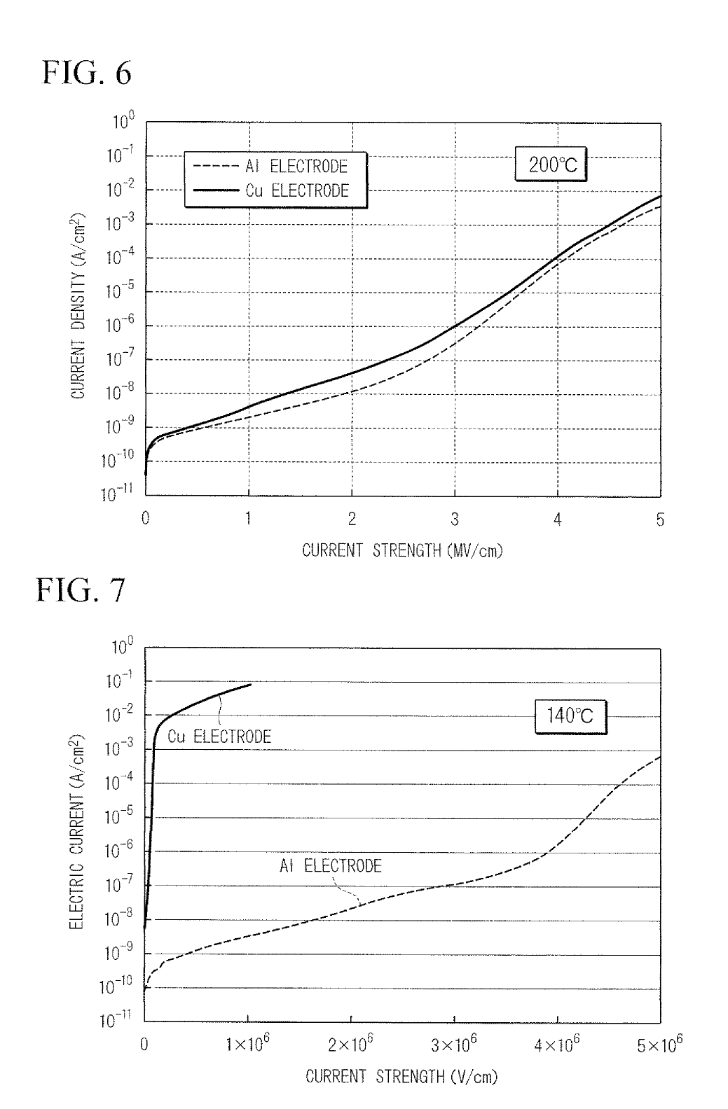

The evaluation results of copper diffusion barrier properties are shown in FIG. 6.

### Comparative Example 1

### Formation of an Insulating Film Wherein a Material Gas which does not Include the Cyclic Structure of CH₂ was Used

An insulating film was prepared such that the method and devices used in Comparative Example 1 were similar to those of Example 1 except that tetravinylsilane was allowed to flow at the volume flow rate of 30 cc/min as a material gas, helium was allowed to flow as a carrier gas at the volume flow rate of 30 cc/min, and output of a high frequency power supply device for generating plasma was 100 W to form an insulating film. When the film was formed, the internal pressure of a chamber of the plasma CVD device was 798 Pa.

The dielectric constant, copper diffusion barrier properties and the thickness of the obtained insulating film were evaluated similar to those of Example 1.

The evaluation results are shown in Table 1.

The evaluation results of copper diffusion barrier properties are shown in FIG. 7.

### Comparative Example 2

### Formation of an Insulating Film Wherein a Material Gas which does not Include the Cyclic Structure of CH₂ was Used

An insulating film was prepared such that the method and devices used in Comparative Example 1 were similar to those of Example 1 except that diallyl divinyl silane was allowed to flow at the volume flow rate of 30 cc/min as a material gas, helium was allowed to flow as a carrier gas at the rate of 30 cc/min, and output of a high frequency power supply device for generating plasma was 100 W to form an insulating film. When the film was formed, the internal pressure of a chamber of the plasma CVD device was 133 Pa.

Dielectric constant, copper diffusion barrier properties and thickness of the obtained insulating film were evaluated similar to those of Example 1.

The evaluation results are shown in Table 1.

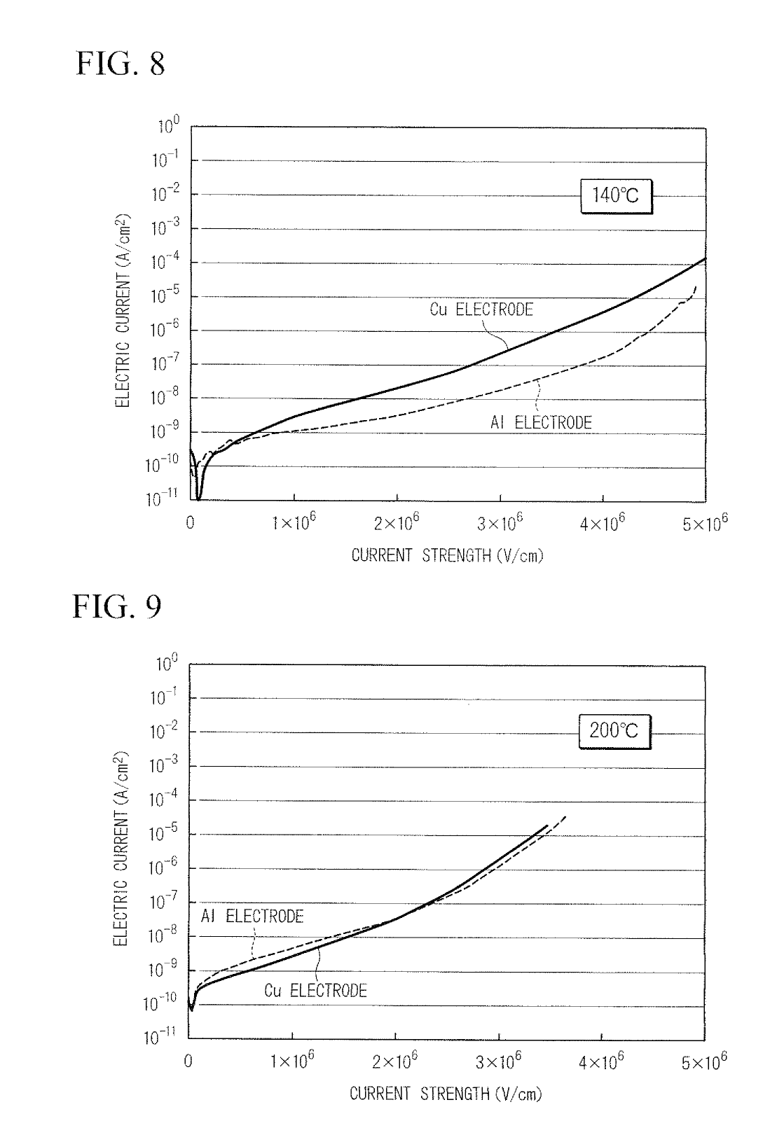

The evaluation results of copper diffusion barrier properties are shown in FIG. 8.

### Comparative Example 3

### Reference Example

### Formation of an Insulating Film Wherein a Material Gas which Includes a Partial Cyclic Structure of CH₂ was Used

An insulating film was prepared such that the method and devices used in Comparative Example 3 were similar to those of Example 1 except that 1,1-divinyl-1-silacyclopentane, which had one cyclic structure which bonds with silicon and consisted of CH₂, was allowed to flow at the volume flow rate of 17 cc/min as a material gas, helium was allowed to flow as a carrier gas at the rate of 40 cc/min, and output of a high frequency power supply device for generating plasma was 150 W to form an insulating film. When the film was formed, the internal pressure of a chamber of the plasma CVD device was 133 Pa.

Here, 1,1-divinyl-1-silacyclopentane is a compound wherein the suitable effects thereof as an insulating film material were discovered by the inventors of the present invention. (Refer to Japanese Unexamined Patent Application, First Publication No. 2009-176898). Accordingly, if a compound shows the effects which are similar or exceed the effects of 1,1-divinyl-1-silacyclopentane, it is possible to arrive at the conclusion that the target effects can be achieved by the compound.

The dielectric constant, copper diffusion barrier properties and the thickness of the obtained insulating film were evaluated similar to those of Example 1.

The evaluation results were shown in Table 1.

The evaluation results of copper diffusion barrier properties are shown in FIG. 9.

TABLE 1

| | Dielectric | Copper diffusion barrier |
|---|---|---|
| | constant | properties |
| Example 1 | 3.22 | Confirmed |
| Example 2 | 3.55 | Confirmed |
| Example 3 | 3.39 | Confirmed |
| Comparative Example 1 | 2.87 | None |
| Comparative Example 2 | 2.72 | None |
| Comparative Example 3 | 3.38 | Confirmed |

From the graphs shown in FIGS. 4 to 9 and the results shown in Table 1, it was confirmed that the insulating film obtained in Example 1 had a dielectric constant of 3.22 and had copper diffusion barrier properties, the insulating film obtained in Example 2 had a dielectric constant of 3.55 and had copper diffusion barrier properties, and the insulating film obtained in Example 3 had a dielectric constant of 3.39 and had copper diffusion barrier properties. In this way, in Examples 1 to 3, insulating films were obtained which had a low dielectric constant and had copper diffusion barrier properties. Although small difference between I-V characteristics was confirmed in Example 3 as compared with other Examples, such small difference does not cause problems.

On the other hand, the insulating film obtained in Comparative Example 1 had a dielectric constant of 2.87 and did not have copper diffusion barrier properties, and the insulating film obtained in Comparative Example 2 had a dielectric constant of 2.72 and did not have copper diffusion barrier properties. In this way, in Comparative Examples 1 and 2, insulating films were obtained which had a low dielectric constant but did not have copper diffusion barrier properties. The insulating film which was prepared in Comparative Example 3 (Reference example) had a dielectric constant of 3.38 and had copper diffusion barrier properties. Accordingly, it was found that Examples 1 to 3 showed the effects which were more than or equal to the effects of Comparative Example 3 (Reference example), and therefore, it was confirmed that the films obtained in Examples 1 to 3 had similar properties to those of a conventional excellent material which had both copper diffusion barrier properties and a low dielectric constant.

### Examples 4 to 8

Although 5-silaspiro[4.4]nonane was used in Examples 1 to 3, other compounds which are included in the scope of the present invention also can show excellent effects. Experiments were performed similar to Example 1 except that following compounds were used instead of 5-silaspiro[4.4]nonane. Insulating films which had a low dielectric constant and copper diffusion barrier properties were obtained in all cases wherein the following compounds were used.

TABLE 2

| | | Dielectric | Copper diffusion |
|---|---|---|---|
| | | constant | barrier properties |
| Example 4 | 5-silaspiro[4.5]decane | 3.50 | Confirmed |
| Example 5 | 5-silaspiro[4.6]undecane | 3.46 | Confirmed |
| Example 6 | 6-silaspiro[5.5]undecane | 3.38 | Confirmed |
| Example 7 | 6-silaspiro[5.6]dodecane | 3.39 | Confirmed |
| Example 8 | 7-silaspiro[6.6]tridecane | 3.25 | Confirmed |

In this way, it is possible to obtain an insulating film which has a low dielectric constant and copper diffusion barrier properties, when an insulating film is formed by plasma CVD method using an insulating film material which is the aforementioned silicon material represented by the chemical formula (1). Furthermore, when an insulating film is formed without a carrier gas such as helium, it is possible to form an insulating film which has an even lower dielectric constant and is suitably used for next generation device. Such an insulating film is suitably used as a copper diffusion barrier type insulating film. Furthermore, an insulating film of the present invention can be preferably used as an interlayer dielectric. When an insulating film of the present invention is used as an interlayer dielectric, it is possible to omit a copper diffusion barrier type insulating film as necessary.

### INDUSTRIAL APPLICABILITY

The present invention can be applied to a next generation semiconductor device, which is required to use highly integrated LSI wiring.

### BRIEF DESCRIPTION OF THE REFERENCE SYMBOLS

1 Chamber
2 Exhaust pipe
3 On-off valve
4 Exhaust pump
5 Upper electrode
6 Lower electrode
7 High frequency power source
8 Substrate
9 Heater
10 Gas supply pipeline

1. An insulating film material for plasma CVD, wherein the material is represented by the chemical formula (1): 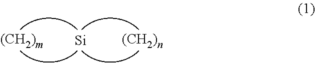
(in the formula, m and n represent integer of 3 to 6, and m and n may be the same or different from each other in a molecule.)

2. The insulating film material for plasma CVD according to claim 1, wherein a molecule of the insulating film material includes no oxygen.

3. The insulating film material for plasma CVD according to claim 1, wherein a molecule of the insulating film material includes no carbon-carbon double bond.

4. The insulating film material for plasma CVD according to claim 1, wherein a molecule of the insulating film material includes two ring structures, which consist of CH₂ and bond to silicon.

5. A film forming method, wherein an insulating film is formed by plasma CVD using the insulating film material according to claim 1.

6. The film forming method according to claim 5, wherein carrier gas does not exist with the insulating film, when the insulating film is formed.

7. An insulating film, which is obtained by the film forming method according to claim 5.

8. The insulating film according to claim 3, wherein the insulating film has a dielectric constant of 3.5 or less.

9. Use of the insulating film material according to claim 1, to form an insulating film by plasma CVD method.

10. The use of the insulating film material according to claim 9, wherein the insulating film formed by the plasma CVD method is an interlayer dielectric film of a multilayered wiring structure which includes a wiring layer and the interlayer dielectric film.

11. The use of the insulating film material according to claim 9, wherein the insulating film formed by the plasma CVD method is an insulating film having copper diffusion barrier properties in a multilayered wiring structure, which includes a wiring layer, the insulating film having copper diffusion barrier properties, and an interlayer dielectric film.

12. The insulating film according to claim 7, wherein a dielectric constant of the insulating film is 2.9 to 3.5.
